(19) United States
(12) Patent Application Publication
(10) Pub. No.: US 2026/0229788 A1
(43) Pub. Date: Aug. 6, 2026

(54) RADIO WAVE ABSORPTION DEVICE

(71) Applicant: Japan Display Inc., Tokyo (JP)

(72) Inventors: Kazuki MATSUNAGA, Tokyo (JP); Shinichiro OKA, Tokyo (JP); Mitsutaka OKITA, Tokyo (JP); Daiichi SUZUKI, Tokyo (JP)

(73) Assignee: Japan Display Inc., Tokyo (JP)

(21) Appl. No.: 19/578,920

(22) Filed: Mar. 26, 2026

Related U.S. Application Data
(63) Continuation of application No. PCT/JP2024/037152, filed on Oct. 18, 2024.

(30) Foreign Application Priority Data
Oct. 24, 2023 (JP) 2023-182676

(51) Int. Cl. H01Q 17/00; H01Q 9/04

(52) U.S. Cl. CPC H01Q 17/007; H01Q 9/0414

(57) ABSTRACT

A radio wave absorption device includes a patch electrode; a counter electrode facing the patch electrode and formed of a material different from a material of the patch electrode; and a liquid crystal layer between the patch electrode and the counter electrode. Another radio wave absorption devices includes a first patch electrode; a second patch electrode independently controllable from the first patch electrode; a counter electrode facing the first patch electrode and the second patch electrode; and a liquid crystal layer between the first patch electrode and the counter electrode and between the second patch electrode and the counter electrode, wherein a first relative permittivity of the liquid crystal layer sandwiched between the first patch electrode and the counter electrode is different from a second relative permittivity of the liquid crystal layer sandwiched between the second patch electrode and the counter electrode.

### CROSS-REFERENCE TO RELATED APPLICATIONS

This application is a Continuation of International Patent Application No. PCT/JP2024/037152, filed on Oct. 18, 2024, which claims the benefit of priority to Japanese Patent Application No. 2023-182676 filed on Oct. 24, 2023, the entire contents of which are incorporated herein by reference.

### FIELD

An embodiment of the present invention relates to a radio wave absorption device that can absorb incident radio waves and a radio wave absorption system equipped with the radio wave absorption device.

### BACKGROUND

In recent years, devices utilizing high frequencies of 10 GHz to 100 GHz have become widely prevalent (Japanese Patent Application Laid-Open No. 2022-047398). Accordingly, problems such as radio wave interference or congestion have occurred among a plurality of high-frequency devices. To solve such problems, the demand for radio wave absorption devices that reduce radio wave interference or congestion has increased.

### SUMMARY

A radio wave absorption device according to an embodiment of the present invention includes: a patch electrode; a counter electrode facing the patch electrode and formed of a material different from a material of the patch electrode; and a liquid crystal layer between the patch electrode and the counter electrode.

A radio wave absorption device according to an embodiment of the present invention includes: a first patch electrode; a second patch electrode independently controllable from the first patch electrode; a counter electrode facing the first patch electrode and the second patch electrode; and a liquid crystal layer between the first patch electrode and the counter electrode and between the second patch electrode and the counter electrode, wherein a first relative permittivity of the liquid crystal layer sandwiched between the first patch electrode and the counter electrode is different from a second relative permittivity of the liquid crystal layer sandwiched between the second patch electrode and the counter electrode.

A radio wave absorption system according to an embodiment of the present invention includes: the radio wave absorption device described above; and a control device configured to control voltages supplied to the patch electrode and the counter electrode, wherein the control device is configured to control the voltages supplied to the patch electrode and the counter electrode to vary an absorption amount of the radio wave absorption device with respect to radio waves having an arbitrary frequency.

A radio wave absorption system according to an embodiment of the present invention includes: the radio wave absorption device described above; and a control device configured to control voltages supplied to the first patch electrode, the second patch electrode and the counter electrode, wherein the control device is configured to control the voltages supplied to the first patch electrode, the second patch electrode and the counter electrode to vary an absorption amount of the radio wave absorption device with respect to radio waves having an arbitrary frequency.

### BRIEF DESCRIPTION OF DRAWINGS

FIG. 1 is a cross-sectional view and a functional block diagram showing an overview of a radio wave absorption system according to an embodiment of the present invention.

FIG. 2 is a cross-sectional view showing an overview of a radio wave absorption device according to an embodiment of the present invention.

FIG. 3A is a plan view of an absorbing surface unit cell used in a radio wave absorption device according to an embodiment of the present invention.

FIG. 3B is a cross-sectional structure of an absorbing surface unit cell used in a radio wave absorption device according to an embodiment of the present invention.

FIG. 4A is a diagram showing a state in which no control voltage is applied between a patch electrode and a counter electrode in an absorbing surface unit cell used in a radio wave absorption device according to an embodiment of the present invention.

FIG. 4B is a diagram showing a state in which a control voltage is applied between a patch electrode and a ground electrode in an absorbing surface unit cell used in a radio wave absorption device according to an embodiment of the present invention.

FIG. 5 shows simulation results showing a relationship between a voltage supplied to a patch electrode and a ground electrode and a frequency band in which radio waves are absorbed, in a radio wave absorption device according to an embodiment of the present invention.

FIG. 6 shows simulation results showing a frequency band in which radio waves are absorbed, in a radio wave absorption device according to an embodiment of the present invention.

FIG. 7 shows simulation results showing a relationship between electrical conductivity of a patch electrode and a ground electrode and radio wave absorption, in a radio wave absorption device according to an embodiment of the present invention.

FIG. 8 is a diagram showing a configuration of a radio wave absorption device of a collective control method according to an embodiment of the present invention.

FIG. 9 is a diagram showing a configuration of a radio wave absorption device of an individual control method according to an embodiment of the present invention.

FIG. 10 is a cross-sectional structure of an absorbing surface unit cell in a radio wave absorption device according to an embodiment of the present invention.

FIG. 11 is a diagram illustrating a driving method for a radio wave absorption device according to an embodiment of the present invention.

FIG. 12 shows simulation results showing a relationship between a driving method for a radio wave absorption device and radio wave absorption, in a radio wave absorption device according to an embodiment of the present invention.

FIG. 13 is a diagram illustrating a driving method for a radio wave absorption device according to an embodiment of the present invention.

FIG. 14 is a diagram illustrating a driving method for a radio wave absorption device according to an embodiment of the present invention.

FIG. 15 shows simulation results showing a relationship between a driving method for a radio wave absorption device and radio wave absorption, in a radio wave absorption device according to an embodiment of the present invention.

FIG. 16 shows simulation results showing a relationship between a thickness of a substrate and radio wave absorption, in a radio wave absorption device according to an embodiment of the present invention.

FIG. 17 shows simulation results showing a relationship between a thickness of a liquid crystal layer and radio wave absorption, in a radio wave absorption device according to an embodiment of the present invention.

FIG. 18 is a cross-sectional view showing an overview of a radio wave absorption device according to an embodiment of the present invention.

FIG. 19 is a plan view showing an overview of a patch electrode of a radio wave absorption device according to an embodiment of the present invention.

### DESCRIPTION OF EMBDOIMENTS

Hereinafter, embodiments of the present invention will be described with reference to the drawings and the like. However, the present invention can be implemented in many different aspects, and should not be construed as being limited to the description of the embodiments exemplified below. The width, thickness, shape, and the like of each part may be schematically represented in comparison with the actual embodiments in order to clarify the description, but the drawings are merely examples and do not limit the interpretation of the present invention. In the present specification and the drawings, elements similar to those described above with respect to the above-described figures are denoted by the same reference signs (or reference signs denoted by a, b, and the like) and detailed description thereof may be omitted as appropriate. Furthermore, the terms “first” and “second” with respect to the respective elements are convenient signs used to distinguish the respective elements, and do not have any further meaning unless otherwise specified.

In the present specification, a member or region is “on (or under)” another member or region, including, without limitation, when it is directly above (or below) another member or region, but also when it is above (or below) another member or region. That is, the above expressions include the case where another component is included between a member or region and another member or region.

In the present specification, the expressions “α includes A, B or C,” “α includes any of A, B and C,” and “α includes one selected from a group consisting of A, B, and C” do not exclude the case where α includes a plurality of combinations of A to C unless otherwise specified. Furthermore, these expressions do not exclude the case where α includes other elements.

In addition, the following embodiments may be combined with each other as long as no technical contradiction is caused.

Conventional radio wave absorption devices are designed to absorb radio waves in a specific frequency. Therefore, after the radio wave absorption device is installed, the frequency of radio waves absorbed by the radio wave absorption device cannot be changed. Furthermore, conventional radio wave absorption devices also cannot be switched between a state of absorbing radio waves and a state of reflecting radio waves.

One object of an embodiment according to the present invention is to provide a radio wave absorption device in which the performance of absorbing radio waves can be adjusted.

### 1. First Embodiment

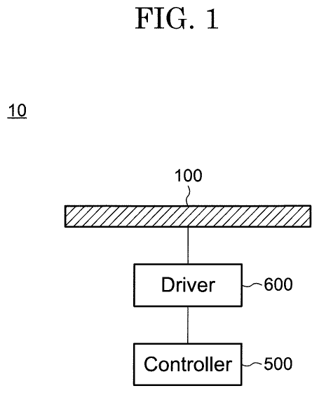

A radio wave absorption system 10 according to an embodiment of the present invention will be described with reference to FIG. 1 to FIG. 10.

### [1-1. Radio Wave Absorption System 10]

FIG. 1 is a cross-sectional view and a functional block diagram showing an overview of a radio wave absorption system according to an embodiment of the present invention. As shown in FIG. 1, the radio wave absorption system 10 includes a radio wave absorption device 100, a control circuit 500, and a drive circuit 600.

The radio wave absorption device 100 absorbs radio waves in a predetermined frequency band. Although a detailed configuration of the radio wave absorption device 100 will be described later, the radio wave absorption device 100 includes a patch electrode, a counter electrode, and a liquid crystal layer. In the radio wave absorption device 100, an alignment of liquid crystal molecules included in the liquid crystal layer is controlled according to voltages (control voltages) supplied to the patch electrode and the counter electrode. By controlling the alignment of the liquid crystal molecules, the frequency band of the radio waves absorbed by the radio wave absorption device 100 is controlled.

Based on an input setting value (for example, a frequency value), the control circuit 500 outputs a control signal corresponding to the setting value. For example, when a user inputs a predetermined frequency value via a user interface provided by the radio wave absorption system 10, the control circuit 500 outputs a control signal for controlling the radio wave absorption device 100 to absorb radio waves of that frequency based on the input frequency value. For example, the control circuit 500 may generate the control signal by performing calculation processing using the input setting value as a parameter. Alternatively, the control circuit 500 may be provided with a lookup table (LUT) in which the setting value and the control signal are associated, and may read out the generated signal by referring to the LUT using the input setting value.

The drive circuit 600 is connected to the control circuit 500 and the radio wave absorption device 100. Based on the control signal output by the control circuit 500, the drive circuit 600 drives the radio wave absorption device 100 (supplies a drive voltage to the radio wave absorption device 100). That is, the drive circuit 600 supplies a control voltage to the patch electrode and the counter electrode of the radio wave absorption device 100 so as to absorb radio waves in a frequency band corresponding to the setting value input by the user. When a plurality of patch electrodes and counter electrodes is provided to the radio wave absorption device 100, the drive circuit 600 may control the plurality of patch electrodes and counter electrodes collectively, may control the plurality of patch electrodes in groups, or may control each of the plurality of patch electrodes individually.

The control circuit 500 and the drive circuit 600 may be collectively referred to as a “control device”. In this case, it can be said that the control device controls the voltages supplied to the patch electrode and the counter electrode. In other words, the control device controls the voltages supplied to the patch electrode and the counter electrode to change an absorption amount of the radio wave absorption device 100 with respect to radio waves having an arbitrary frequency. In other words, the control device receives, via an interface, a setting value related to the frequency of the radio waves to be absorbed by the radio wave absorption device 100, and controls the voltages supplied to the patch electrode and the counter electrode based on the setting value.

### [1-2. Radio Wave Absorption Device 100]

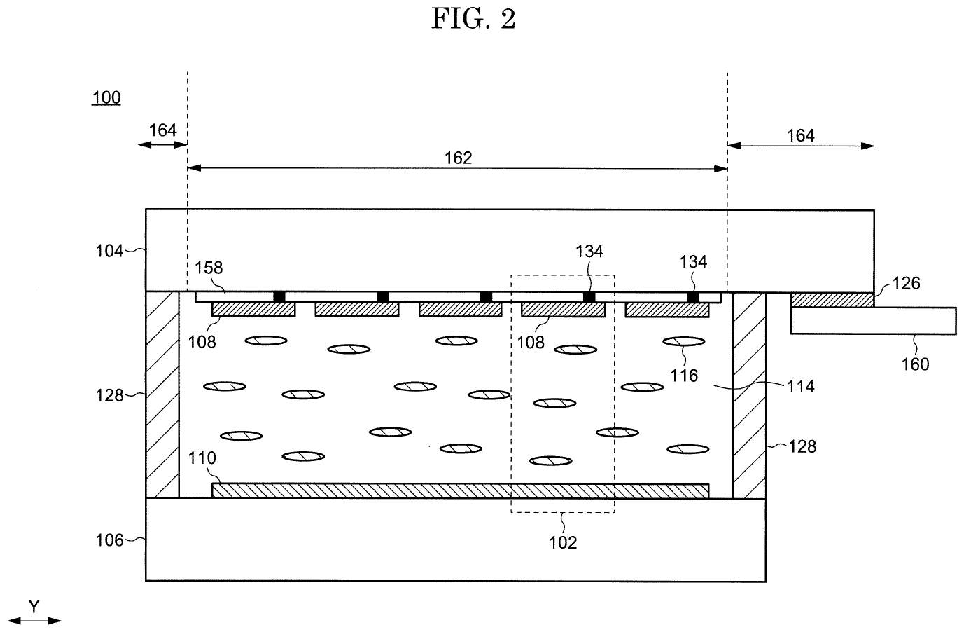

FIG. 2 is a cross-sectional view showing an overview of a radio wave absorption device according to an embodiment of the present invention. As shown in FIG. 2, the radio wave absorption device 100 includes a plurality of absorbing elements (absorbing surface unit cells 102). The plurality of absorbing surface unit cells 102 is arranged in at least one direction. In FIG. 2, the plurality of absorbing surface unit cells 102 is arranged in a Y-axis direction. The radio wave absorption device 100 includes a dielectric substrate 104, a counter substrate 106, a patch electrode 108, a ground electrode 110, a liquid crystal layer 114, a sealing material 128, a switching element 134, a terminal portion 126, and a flexible printed circuit substrate (FPC) 160. The liquid crystal layer 114 contains a liquid crystal molecule 116. A passivation layer 158 is provided between the patch electrode 108 and the dielectric substrate 104.

In the radio wave absorption device 100, among the opposing electrodes (the patch electrode 108 and the ground electrode 110), the electrode provided on the radio wave incident surface side is referred to as the “patch electrode”, and the electrode opposing the patch electrode is referred to as the “counter electrode”. In the present embodiment, the ground electrode 110 corresponds to the counter electrode. Although details will be described later, when radio waves are incident from the counter substrate 106 side, the electrode corresponding to the ground electrode 110 is referred to as the patch electrode.

Although details will be described later, when the radio wave absorption device 100 controls the plurality of absorbing surface unit cells 102 individually or in groups, each absorbing surface unit cell 102 includes the switching element 134. On the other hand, when the radio wave absorption device 100 controls the plurality of absorbing surface unit cells 102 collectively, each absorbing surface unit cell 102 may not include the switching element 134.

The absorbing surface unit cell 102 includes at least the patch electrode 108, the ground electrode 110 (counter electrode), the liquid crystal layer 114, and the switching element 134. The patch electrode 108 is individually provided for each absorbing surface unit cell 102. The patch electrode 108 is provided on the dielectric substrate 104 side. The ground electrode 110 faces the patch electrode 108 and is commonly provided for the plurality of absorbing surface unit cells 102. The ground electrode 110 is provided on the counter substrate 106 side. A detailed structure of the absorbing surface unit cell 102 will be described later.

The liquid crystal layer 114 is provided between the patch electrode 108 and the ground electrode 110. An alignment of the liquid crystal molecule 116 contained in the liquid crystal layer 114 is controlled by the control voltages supplied to the patch electrode 108 and the ground electrode 110. The sealing material 128 is provided to surround the periphery of the counter substrate 106. In other words, the liquid crystal layer 114 is sealed with the sealing material 128. The patch electrode 108 and the ground electrode 110 are provided in a region surrounded by the sealing material 128.

A material of the patch electrode 108 is different from a material of the ground electrode 110. The electrical conductivity (or electrical conductance) of a material forming the patch electrode 108 is different from the electrical conductivity of a material forming the ground electrode 110. For example, the ratio of the electrical conductivity of the material forming the patch electrode 108 to the electrical conductivity of the material forming the ground electrode 110 is 10 times or more. Although details will be described later, the amount of radio waves absorbed by the radio wave absorption device 100 is affected by the balance of the electrical conductivity of each of the patch electrode 108 and the ground electrode 110. Since the electrical conductivity of each of the patch electrode 108 and the ground electrode 110 exhibits the above characteristics, the amount of radio waves absorbed by the radio wave absorption device 100 can be increased.

The radio wave absorption device 100 is divided into a radio wave absorbing region 162 and a peripheral region 164 surrounding the radio wave absorbing region 162. The radio wave absorbing region 162 is a region where the patch electrode 108 and the ground electrode 110 are arranged. The radio wave incident on the radio wave absorption device 100 from the dielectric substrate 104 side is absorbed in the radio wave absorbing region 162. By supplying the control voltage between the patch electrode 108 and the ground electrode 110 and controlling the alignment of the liquid crystal molecule 116, the radio wave incident on the radio wave absorption device 100 is absorbed by the patch electrode 108. That is, the patch electrode 108 functions as a receiving antenna for the incident radio waves. Since the reflection characteristics of the receiving antenna can be controlled by the control voltage supplied between the patch electrode 108 and the ground electrode 110, the frequency band of the radio waves absorbed by the patch electrode 108 can be controlled by controlling the control voltage. Although not shown, a part of the drive circuit 600 is arranged in the peripheral region 164.

The switching element 134 is connected to the patch electrode 108. The switching element 134 is provided at a position close to the radio wave incident surface with respect to the patch electrode 108. The switching element 134 is driven by the drive circuit 600 (see FIG. 1). The alignment of the liquid crystal molecule 116 is controlled according to the driving state of the switching element 134. Although details will be described later, by controlling the alignment of the liquid crystal molecule 116, the frequency band of the radio waves absorbed by the radio wave absorption device 100 is controlled.

The terminal portion 126 is provided at the end portion of the dielectric substrate 104. The terminal portion 126 may be formed in the same layer as the patch electrode 108. The terminal portion 126 may be in the same layer as a part or all of the conductive layers forming the switching element 134. The terminal portion 126 is connected to the switching element 134 via a wiring. The FPC 160 is connected to the terminal portion 126. The drive circuit 600 drives the switching element 134 in response to a control signal input from the outside via the FPC 160.

### [1-3. Absorbing Surface Unit Cell]

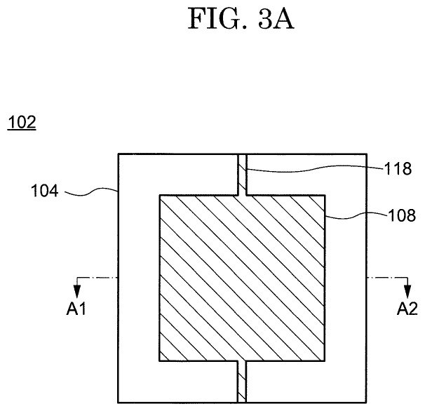

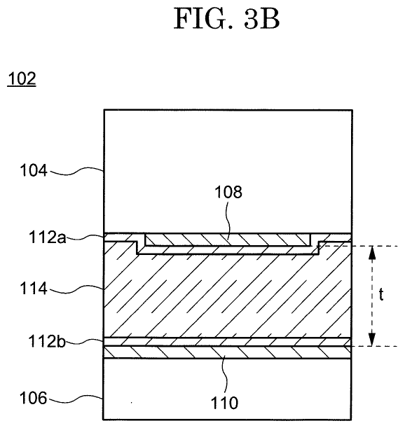

FIG. 3A and FIG. 3B are a plan view and a cross-sectional structure of an absorbing surface unit cell used in a radio wave absorption device according to an embodiment of the present invention, respectively. FIG. 3A is a plan view of the absorbing surface unit cell 102 when viewed from above (the side where radio waves are incident). FIG. 3B is a cross-sectional view between A1-A2 shown in the plan view.

As shown in FIG. 3A and FIG. 3B, the absorbing surface unit cell 102 includes the dielectric substrate 104, the counter substrate 106, the patch electrode 108, the ground electrode 110, the liquid crystal layer 114, a first alignment film 112a, and a second alignment film 112b. Within the absorbing surface unit cell 102, the dielectric substrate 104 may be regarded as one layer (dielectric layer). The patch electrode 108 is provided on the dielectric substrate 104, and the ground electrode 110 is provided on the counter substrate 106. The first alignment film 112a is provided on the dielectric substrate 104 to cover the patch electrode 108. The second alignment film 112b is provided on the counter substrate 106 to cover the ground electrode 110. The patch electrode 108 and the ground electrode 110 are arranged to face each other, and the liquid crystal layer 114 is provided between the patch electrode 108 and the ground electrode 110. The first alignment film 112a is interposed between the patch electrode 108 and the liquid crystal layer 114. The second alignment film 112b is interposed between the ground electrode 110 and the liquid crystal layer 114.

The patch electrode 108 preferably has a shape that is symmetrical with respect to the vertically polarized wave and horizontally polarized wave of incident radio waves. For example, the patch electrode 108 has a square or circular shape in a plan view. FIG. 3A shows the case where the patch electrode 108 is square in a plan view. There is no particular limitation on the shape of the ground electrode 110, and the ground electrode 110 has a shape that spreads over substantially the entire surface of the counter substrate 106 to have a larger area than the patch electrode 108. There is no limitation on the material forming the patch electrode 108 and the ground electrode 110 except that the material of the patch electrode 108 is different from the material of the ground electrode 110. The patch electrode 108 and the ground electrode 110 are formed using a conductive metal or a metal oxide. A first wiring 118 is provided on the dielectric substrate 104. The first wiring 118 is connected to the patch electrode 108. The first wiring 118 is used when the control voltage is supplied to the patch electrode 108. When the plurality of absorbing surface unit cells 102 is aligned in the radio wave absorption device 100, the first wiring 118 is used to connect a certain patch electrode 108 to an adjacent patch electrode 108.

Although not shown in FIG. 3A and FIG. 3B, the dielectric substrate 104 and the counter substrate 106 are bonded together by the sealing material 128. The dielectric substrate 104 and the counter substrate 106 are arranged to face each other with a gap. The liquid crystal layer 114 is provided within the region surrounded by the sealing material 128. The liquid crystal layer 114 is provided to fill the gap between the dielectric substrate 104 and the counter substrate 106.

For example, when the shape of the patch electrode 108 is a square with a side length of approximately 2 mm, a distance between the dielectric substrate 104 and the counter substrate 106 is 5 μm or more and 100 μm or less, 10 μm or more and 40 μm or less, or 15 μm or more and 25 μm or less. In other words, the ratio of the distance between the dielectric substrate 104 and the counter substrate 106 to the side length of the patch electrode 108 (approximately 2 mm) is 0.25% or more and 5% or less, 0.5% or more and 2% or less, or 0.75% or more and 1.25% or less.

The patch electrode 108, the ground electrode 110, the first alignment film 112a, and the second alignment film 112b are provided between the dielectric substrate 104 and the counter substrate 106. Therefore, precisely, a distance between the first alignment film 112a and the second alignment film 112b provided on each of the dielectric substrate 104 and the counter substrate 106 is the thickness of the liquid crystal layer 114. Although not shown in FIG. 3B, a spacer for keeping the distance constant may be provided between the dielectric substrate 104 and the counter substrate 106.

A control voltage for controlling the alignment of the liquid crystal molecule 116 of the liquid crystal layer 114 is supplied to the patch electrode 108. For example, the control voltage is a DC voltage signal or a polarity inversion voltage signal in which a positive DC voltage and a negative DC voltage are alternately inverted. In the case of the polarity inversion voltage signal in which a positive DC voltage and a negative DC voltage are alternately inverted, a voltage at a ground level or an intermediate level of the polarity inversion voltage is supplied to the ground electrode 110. When the control voltage is supplied to the patch electrode 108, the alignment status of the liquid crystal molecules contained in the liquid crystal layer 114 changes. A liquid crystal material having dielectric anisotropy is used for the liquid crystal layer 114. For example, a nematic liquid crystal, a smectic liquid crystal, a cholesteric liquid crystal, or a discotic liquid crystal can be used as the liquid crystal layer 114. The dielectric constant of the liquid crystal layer 114 with dielectric anisotropy changes due to a change in the alignment status of the liquid crystal molecules. The absorbing surface unit cell 102 can change the dielectric constant of the liquid crystal layer 114 by the control voltage supplied to the patch electrode 108, thereby adjusting the frequency band of the radio waves absorbed by the absorbing surface unit cell 102.

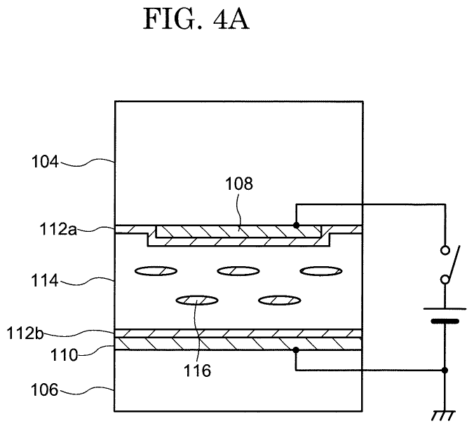

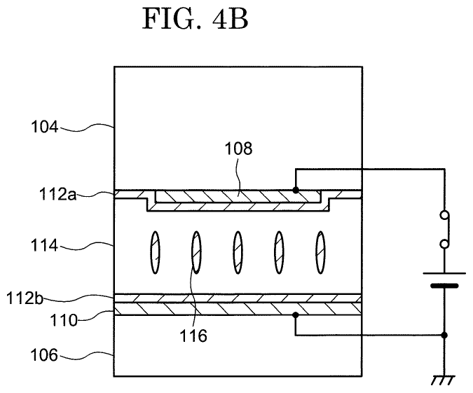

FIG. 4A shows a state in which no voltage is supplied between the patch electrode 108 and the ground electrode 110, or the case where the potential difference between the patch electrode 108 and the ground electrode 110 is zero (referred to as a “first state”). FIG. 4A shows the case where the first alignment film 112a and the second alignment film 112b are horizontal alignment films. The long axes of the liquid crystal molecules 116 in the first state are horizontally aligned with respect to the surfaces of the patch electrode 108 and the ground electrode 110 by the first alignment film 112a and the second alignment film 112b. FIG. 4B shows a state in which the control voltage is supplied to the patch electrode 108 (referred to as a “second state”). In the second state, the long axes of the liquid crystal molecules 116 are vertically aligned with respect to the surfaces of the patch electrode 108 and the ground electrode 110 due to the influence of an electric field. An angle at which the long axis of the liquid crystal molecule 116 is aligned can also be controlled in an intermediate direction between the horizontal direction and the vertical direction, depending on the magnitude of the control voltage supplied to the patch electrode 108 (the voltage magnitude between the counter electrode and the patch electrode).

When the liquid crystal molecule 116 has a positive dielectric anisotropy, the dielectric constant is greater in the second state than in the first state. On the other hand, when the liquid crystal molecule 116 has a negative dielectric anisotropy, the dielectric constant is smaller in the second state than in the first state. In addition, the liquid crystal layer 114 with dielectric anisotropy can be regarded as a variable dielectric layer. The absorbing surface unit cell 102 can adjust the frequency band of the radio waves to be absorbed by utilizing the dielectric anisotropy of the liquid crystal layer 114.

The absorbing surface unit cell 102 is used as an absorbing surface that absorbs radio waves. It is preferable that the absorbing surface unit cell 102 reflects incident radio waves as little as possible. As is clear from the structure shown in FIG. 3B, when radio waves propagating through the air are incident on the absorbing surface unit cell 102, the radio waves pass through the dielectric substrate 104 twice. For example, the dielectric substrate 104 is formed from dielectric materials such as glass or resin. When radio waves pass through the dielectric, the phase velocity of the radio wave changes, so to prevent the amplitude of the reflected wave from becoming large, it is preferable to set the thickness of the dielectric substrate 104 to be a thickness different from ¼ of the wavelength of the incident radio wave (for example, ⅛ of the wavelength).

### [1-4. Simulation Results of Radio Wave Absorption Device 100]

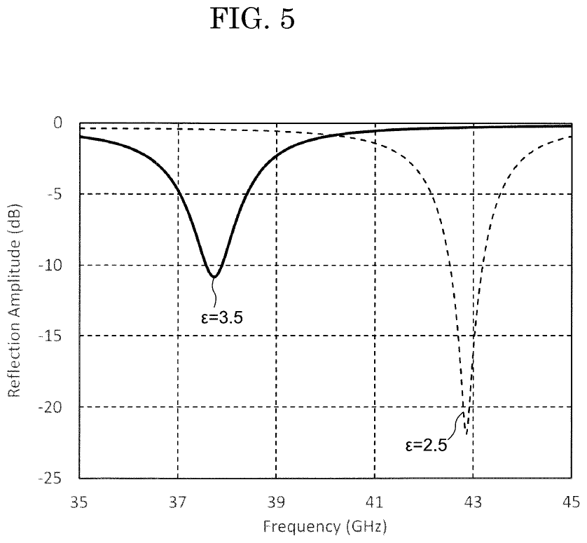

FIG. 5 shows simulation results showing a relationship between the voltage supplied to the patch electrode and the ground electrode and the frequency band in which the radio waves are absorbed, in a radio wave absorption device according to an embodiment of the present invention. The simulation results shown in FIG. 5 are the results of simulating the reflection characteristics of one absorbing surface unit cell 102. In this simulation, calculations were performed based on a model assuming that the periodic structure of the absorbing surface unit cell 102 extends infinitely. This simulation was performed using CST Studio Suite (manufactured by Dassault Systemes K.K.). The parameters of the radio wave absorption device 100 used in the simulation are as follows.
Arrangement pitch of the patch electrode 108: 3 mm
Size of the patch electrode 108: 2 mm×2 mm
Thickness of the liquid crystal layer: 30 μm
Relative permittivity ε of the liquid crystal layer 114: 2.5, 3.5
Thickness of the substrate 101: 1.0 mm

In the graph shown in FIG. 5, the vertical axis represents Reflection Amplitude, and the horizontal axis represents Frequency. In the graph of FIG. 5, a large reflection amplitude (close to zero) means that the radio wave absorption device 100 reflects more of the incident radio wave. That is, in the graph of FIG. 5, the smaller the reflection amplitude (further from zero), the greater the amount of incident radio waves absorbed by the radio wave absorption device 100.

FIG. 5 shows two simulation results. These simulation results are obtained for the liquid crystal layer 114 with different relative permittivities (ε=2.5, 3.5). In FIG. 5, the simulation result when the relative permittivity ε is 2.5 is shown by a dotted line, and the simulation result when the relative permittivity ε is 3.5 is shown by a solid line. In the radio wave absorption device 100, the simulation result when the relative permittivity ε is 2.5 corresponds to the simulation result when no control voltage is supplied to the patch electrode 108 and the ground electrode 110 (a state in which the potential difference between the patch electrode 108 and the ground electrode 110 is zero). On the other hand, the simulation result when the relative permittivity ε is 3.5 corresponds to the simulation result when the control voltages are supplied to the patch electrode 108 and the ground electrode 110. The relative permittivity ε can be adjusted in the range of 2.5 to 3.5 by controlling the control voltages supplied to the patch electrode 108 and the ground electrode 110.

As shown in FIG. 5, when the relative permittivity ε is 2.5, the frequency at which the reflection amplitude has a minimum value is 42.9 GHz. That is, in this case, the radio wave absorption device 100 absorbs radio waves with a frequency of 42.9 GHz most effectively. On the other hand, when the relative permittivity ε is 3.5, the frequency at which the reflection amplitude has a minimum value is 37.4 GHz. That is, in this case, the radio wave absorption device 100 absorbs radio waves with a frequency of 37.4 GHz most effectively.

In other words, for radio waves with a frequency of 42.9 GHz, when the relative permittivity ε is 2.5, the radio wave absorption device 100 absorbs the incident radio waves (42.9 GHz), but when the relative permittivity ε is 3.5, the radio wave absorption device 100 reflects the incident radio waves (42.9 GHz). Similarly, for radio waves with a frequency of 37.4 GHz, when the relative permittivity ε is 2.5, the radio wave absorption device 100 reflects the incident radio waves (37.4 GHz), and when the relative permittivity ε is 3.5, the radio wave absorption device 100 absorbs the incident radio waves (37.4 GHz). That is, the radio wave absorption device 100 can switch between an absorbing state and a reflecting state for radio waves of a certain frequency.

### [1-5. Influence of Materials of Patch Electrode 108 and Ground Electrode 110]

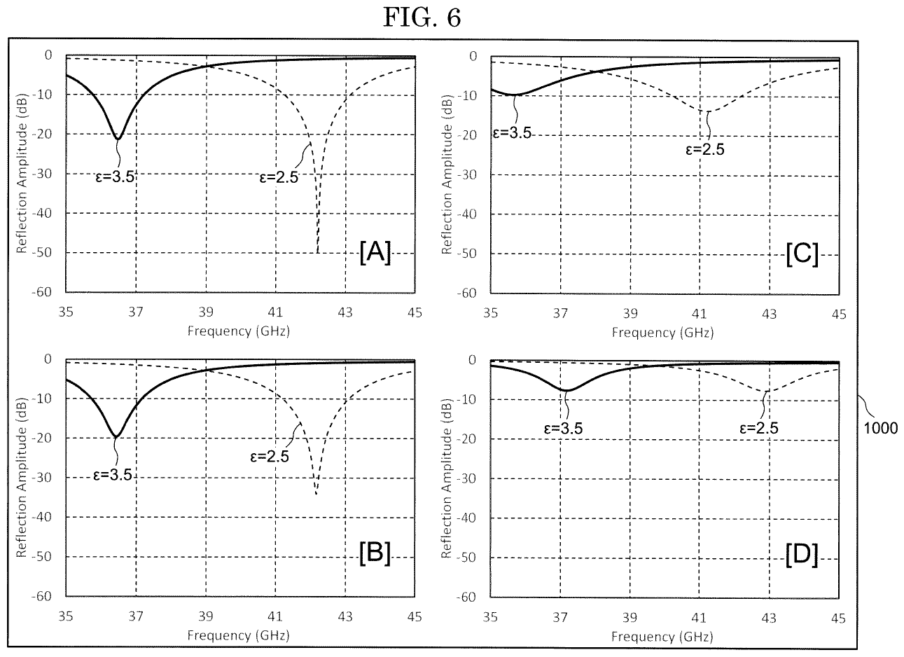

FIG. 6 shows simulation results showing a frequency band in which radio waves are absorbed, in the radio wave absorption device according to an embodiment of the present invention. FIG. 6 shows four simulation results 1000 ([A] to [D]) for different combinations of the patch electrode 108 and the ground electrode 110 as follows. The electrical conductivity of Al used in the simulation shown in FIG. 6 is 3.5×10⁷ [S/m], and the electrical conductivity of ITO is 6.7×10⁵ [S/m].
[A] Patch electrode 108/Ground electrode 110=Al/ITO
[B] Patch electrode 108/Ground electrode 110=ITO/Al
[C] Patch electrode 108/Ground electrode 110=ITO/ITO
[D] Patch electrode 108/Ground electrode 110=Al/Al

As shown in [A] of FIG. 6, when the patch electrode 108/the ground electrode 110 is Al/ITO and the relative permittivity ε of the liquid crystal layer 114 is 2.5, the minimum value of the reflection amplitude is approximately −50 dB. When the patch electrode 108/the ground electrode 110 is Al/ITO and the relative permittivity ε of the liquid crystal layer 114 is 3.5, the minimum value of the reflection amplitude is approximately −21 dB.

As shown in [B] of FIG. 6, when the patch electrode 108/the ground electrode 110 is ITO/Al and the relative permittivity ε of the liquid crystal layer 114 is 2.5, the minimum value of the reflection amplitude is approximately −34 dB. When the patch electrode 108/the ground electrode 110 is ITO/Al and the relative permittivity ε of the liquid crystal layer 114 is 3.5, the minimum value of the reflection amplitude is approximately −20 dB.

As shown in [C] of FIG. 6, when the patch electrode 108/the ground electrode 110 is ITO/ITO and the relative permittivity ε of the liquid crystal layer 114 is 2.5, the minimum value of the reflection amplitude is approximately −14 dB. When the patch electrode 108/the ground electrode 110 is ITO/ITO and the relative permittivity ε of the liquid crystal layer 114 is 3.5, the minimum value of the reflection amplitude is approximately −10 dB.

As shown in [D] of FIG. 6, when the patch electrode 108/the ground electrode 110 is Al/Al whether the relative permittivity ε of the liquid crystal layer 114 is 2.5 or 3.5, the minimum value of the reflection amplitude is approximately −8 dB.

As described above, the minimum value of the reflection amplitude when the materials of the patch electrode 108 and the ground electrode 110 are different ([A], [B]) is smaller than the minimum value of the reflection amplitude when the materials of the patch electrode 108 and the ground electrode 110 are the same ([C], [D]). That is, the radio wave absorption device 100 in which the materials of the patch electrode 108 and the ground electrode 110 are different absorbs more radio waves than the radio wave absorption device 100 in which the materials of the patch electrode 108 and the ground electrode 110 are the same. By making the ratio of the electrical conductivity of the material forming the patch electrode 108 to the electrical conductivity of the material forming the ground electrode 110 10 times or more, the amount of radio waves absorbed by the radio wave absorption device 100 can be further increased. The ratio may be 20 times or more, 30 times or more, or 50 times or more. Similarly, in other words, the material of the patch electrode 108 is one of a metal material and a transparent conductive material, and the material of the ground electrode 110 is the other of the metal material and the transparent conductive material. That is, when the material of the patch electrode is a metal material, the material of the counter electrode is a transparent conductive material, and when the material of the patch electrode is a transparent conductive material, the material of the counter electrode is a metal material.

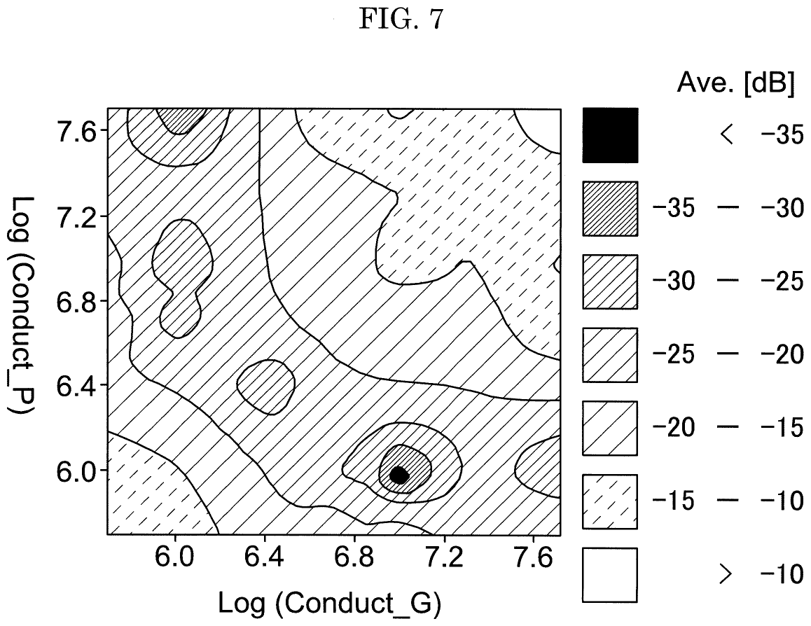

FIG. 7 shows simulation results showing a relationship between the electrical conductivity of the patch electrode and the ground electrode and radio wave absorption, in the radio wave absorption device according to an embodiment of the present invention. In FIG. 7, the horizontal axis shows the common logarithm of the electrical conductivity of the ground electrode 110 (Log (Conduct_G)), and the vertical axis shows the common logarithm of the electrical conductivity of the patch electrode 108 (Log (Conduct_P)). In the two-dimensional map of FIG. 7, regarding the simulation results for each electrical conductivity, the average values of the minimum value of the reflection amplitude when the relative permittivity ε of the liquid crystal layer 114 is 2.5 and the minimum value of the reflection amplitude when the relative permittivity ε of the liquid crystal layer 114 is 3.5 are plotted.

As shown in FIG. 7, the regions where the minimum value of the reflection amplitude is relatively small (regions of −20 dB or less) are distributed in a quadratic curve (curving from the upper left to the lower right of the graph). The regions where the minimum value of the reflection amplitude is −20 dB or less are affected by the balance of the electrical conductivities of the patch electrode 108 and the ground electrode 110, respectively. This is because the smaller the difference between the characteristic impedance of air and the impedance of the meta-surface, the greater the amount of radio waves absorbed by the radio wave absorption device 100.

As described above, according to the radio wave absorption device 100 of the present embodiment, the frequency band of the radio waves absorbed by the radio wave absorption device 100 can be adjusted by the control voltages supplied to the patch electrode 108 and the ground electrode 110.

[1-6. Control Method of Radio wave Absorption Device 100]

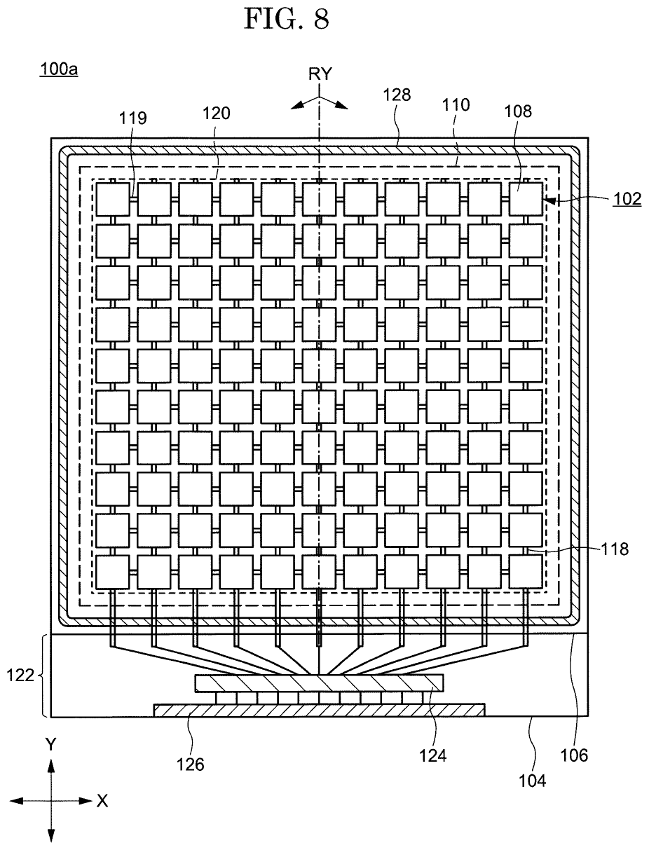

A control method for the radio wave absorption device 100 in which the absorbing surface unit cells 102 are integrated will be described with reference to FIG. 8 to FIG. 10. The control method for the radio wave absorption device 100 includes a collective control method and an individual control method. Each control method will be described below.

### [1-6-1. Collective Control Method]

FIG. 8 is a diagram showing a configuration of a radio wave absorption device of a collective control method according to an embodiment of the present invention. A radio wave absorption device 100a has an absorbing surface 120. The absorbing surface 120 is composed of the plurality of absorbing surface unit cells 102. For example, the plurality of absorbing surface unit cells 102 is arranged in a first direction (X-axis direction shown in FIG. 8) and a second direction (Y-axis direction shown in FIG. 8) intersecting the first direction. The absorbing surface unit cell 102 is arranged so that the patch electrode 108 faces the radio wave incident surface. The absorbing surface 120 is flat and plate-shaped, and a plurality of patch electrodes 108 is arranged in a matrix inside the flat plate-shaped surface. The radio wave absorption device 100a shown in FIG. 8 may not include the switching element 134.

The radio wave absorption device 100a has a structure in which the plurality of absorbing surface unit cells 102 is integrated on one dielectric substrate 104. As shown in FIG. 8, the radio wave absorption device 100a has a structure including the dielectric substrate 104 on which the plurality of patch electrodes 108 is arranged and the counter substrate 106 on which the ground electrode 110 is provided are stacked one on another, with the liquid crystal layer 114 provided between the dielectric substrate 104 and the counter substrate 106. The absorbing surface 120 is formed in a region where the plurality of patch electrodes 108 and the ground electrode 110 overlap. In each patch electrode 108, a cross-sectional structure of the absorbing surface 120 is the same as the structure of the absorbing surface unit cell 102 shown in FIG. 3B. The dielectric substrate 104 and the counter substrate 106 are bonded together with the sealing material 128, and the liquid crystal layer 114 is provided in a region inside the sealing material 128.

The dielectric substrate 104 has a thickness different from ¼ wavelength of the radio wave to be absorbed (for example, a thickness of ⅛ wavelength). The dielectric substrate 104 has a peripheral region 122 extending outward from the counter substrate 106 in addition to a region facing the counter substrate 106. A first drive circuit 124 and the terminal portion 126 are provided in the peripheral region 122. The first drive circuit 124 supplies a control voltage to the patch electrode 108. In this configuration, the first drive circuit 124 corresponds to the drive circuit 600. The terminal portion 126 is connected to an external circuit and is connected to the FPC 160. A signal for controlling the first drive circuit 124 is input to the terminal portion 126.

As described above, the plurality of patch electrodes 108 is arranged in the first direction (X-axis direction) and the second direction (Y-axis direction) in the dielectric substrate 104. A plurality of first wirings 118 extending in the second direction (Y-axis direction) and second wirings 119 extending in the first direction (X-axis direction) are arranged in the dielectric substrate 104. Each of the plurality of first wirings 118 is electrically connected to the plurality of patch electrodes 108 arranged in the second direction (Y-axis direction). In other words, the plurality of patch electrodes 108 arranged in the second direction (Y-axis direction) is connected by the first wiring 118. Similarly, each of the plurality of second wirings 119 electrically connects the plurality of patch electrodes 108 arranged in the first direction (X-axis direction). In other words, the plurality of patch electrodes 108 arranged in the first direction (X-axis direction) is connected by the second wiring 119. The absorbing surface 120 has a configuration in which one matrix-like patch electrode array connected by the first wiring 118 and the second wiring 119 is arranged to spread across the XY plane.

The plurality of first wirings 118 arranged on the absorbing surface 120 extends to the peripheral region 122 and is connected to the first drive circuit 124. The first drive circuit 124 supplies the control voltage to be supplied to the patch electrodes 108. The first drive circuit 124 supplies control voltages at the same voltage level to each of the plurality of first wirings 118. As a result, in the absorbing surface 120, the control voltage is supplied collectively to the plurality of patch electrodes 108 arranged in the first direction (X-axis direction) and the second direction (Y-axis direction).

### [1-6-2. Individual Control Method]

A radio wave absorption device 100b described below can individually control the absorbing surface unit cells 102. In the following description, differences from the radio wave absorption device 100a described above will be mainly described.

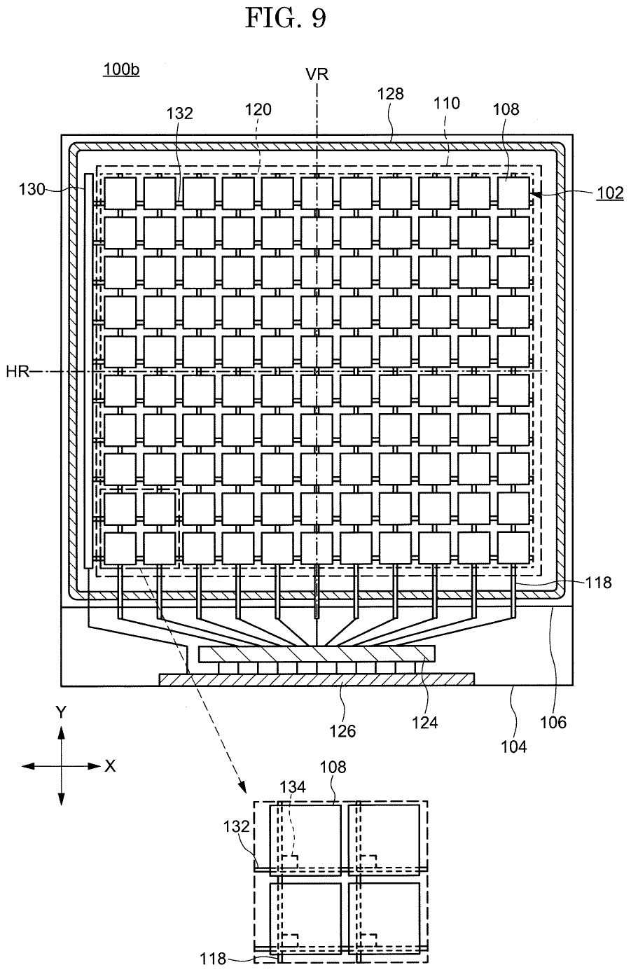

FIG. 9 shows a configuration of the radio wave absorption device 100b according to this embodiment. In the following description, differences from the radio wave absorption device 100a shown in FIG. 8 will be mainly described.

The radio wave absorption device 100b includes a plurality of second wirings 132 extending in the first direction (X-axis direction) in addition to the plurality of first wirings 118 extending in the second direction (Y-axis direction), in the absorbing surface 120. The plurality of first wirings 118 and the plurality of second wirings 132 are arranged to intersect with an insulating layer (not shown) sandwiched between them. That is, the first wiring 118 and the second wiring 132 are insulated from each other. The plurality of first wirings 118 is connected to the first drive circuit 124, and the plurality of second wirings 132 is connected to the second drive circuit 130. The first drive circuit 124 supplies a control voltage, and the second drive circuit 130 outputs a scan signal. In this configuration, the first drive circuit 124 and the second drive circuit 130 correspond to the drive circuit 600. In FIG. 9, the first drive circuit 124 is shown as an embodiment in which an IC chip or the like is mounted on the dielectric substrate 104. Similar to the switching element 134 and the like, the second drive circuit 130 is shown as a drive circuit using a thin-film transistor formed on the dielectric substrate 104. However, the present embodiment is not limited to this configuration.

At the bottom of FIG. 9, an enlarged inset view showing an arrangement of four patch electrodes 108, two first wirings 118, and two second wirings 132 is shown. Each of the four patch electrodes 108 is provided with the switching element 134. The switching (on and off) of the switching element 134 is controlled by the scan signal supplied to the second wiring 132. The patch electrode 108, whose switching element 134 is turned on, conducts with the first wiring 118. The control voltage is supplied to this patch electrode 108 via the switching element 134. For example, the switching element 134 is formed by a thin-film transistor. With this configuration, the plurality of patch electrodes 108 arranged in the first direction (X-axis direction) can be selected by row, and control signals at different voltage levels can be supplied to each row.

The radio wave absorption device 100b shown in FIG. 9 can individually control the absorbing surface unit cells 102. Therefore, as in the first embodiment described above, it is possible to collectively control all the absorbing surface unit cells 102, and as in the second embodiment described below, it is also possible to perform different control for each absorbing surface unit cell 102.

### [1-6-3. Cross-Sectional Structure of Radio Wave Absorption Device 100]

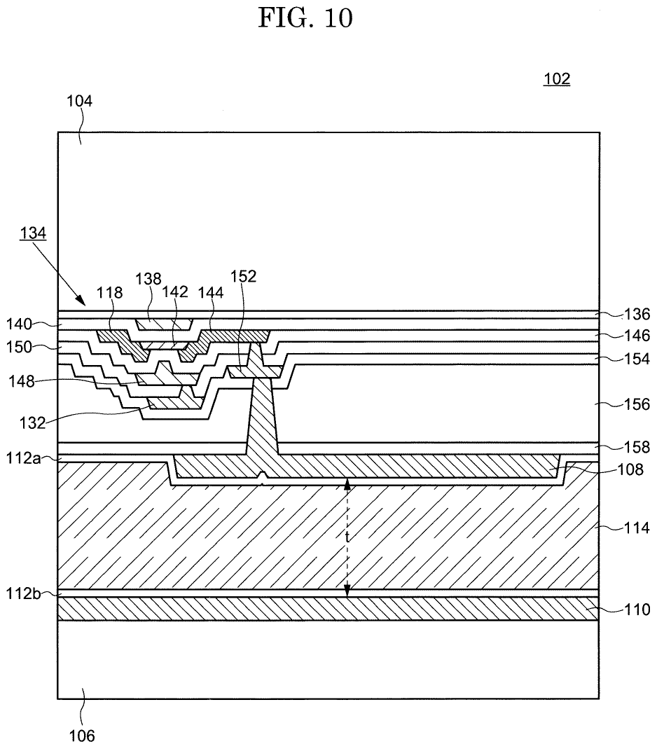

FIG. 10 shows an example of a cross-sectional structure of the absorbing surface unit cell 102 in which the switching element 134 is connected to the patch electrode 108. The switching element 134 is provided on the dielectric substrate 104. The switching element 134 is a transistor and has a stacked structure in which a first gate electrode 138, a first gate insulating layer 140, a semiconductor layer 142, a second gate insulating layer 146, and a second gate electrode 148 are stacked. An undercoat layer 136 may be provided between the first gate electrode 138 and the dielectric substrate 104. The first wiring 118 is provided between the first gate insulating layer 140 and the second gate insulating layer 146. The first wiring 118 is provided to be in contact with the semiconductor layer 142. A first connecting wiring 144 is provided in the same layer as the conductive layer forming the first wiring 118. The first connecting wiring 144 is provided to be in contact with the semiconductor layer 142. The connection structure of the first wiring 118 and the first connecting wiring 144 to the semiconductor layer 142 shows a structure in which one wiring is connected to a source of the transistor and the other wiring is connected to a drain of the transistor.

A first interlayer insulating layer 150 is provided to cover the switching element 134. The second wiring 132 is provided under the first interlayer insulating layer 150. The second wiring 132 is connected to the second gate electrode 148 via a contact hole formed in the first interlayer insulating layer 150. Although not shown, the first gate electrode 138 and the second gate electrode 148 are electrically connected in a region that does not overlap the semiconductor layer 142. A second connecting wiring 152 is provided under the first interlayer insulating layer 150 in the same conductive layer as the second wiring 132. The second connecting wiring 152 is connected to the first connecting wiring 144 via a contact hole formed in the first interlayer insulating layer 150.

A second interlayer insulating layer 154 is provided to cover the second wiring 132 and the second connecting wiring 152. A planarization layer 156 is provided to fill the steps of the switching element 134. The planarization layer 156 is provided, and then the patch electrode 108 can be formed without being affected by the arrangement of the switching element 134. The passivation layer 158 is provided under the flat surface of the planarization layer 156. The patch electrode 108 is provided under the passivation layer 158. The patch electrode 108 is connected to the second connecting wiring 152 via a contact hole that penetrates the passivation layer 158, the planarization layer 156, and the second interlayer insulating layer 154. The first alignment film 112a is provided under the patch electrode 108.

Similar to FIG. 3B, the counter substrate 106 includes the ground electrode 110 and the second alignment film 112b. The surface of the dielectric substrate 104 provided with the switching element 134 and the patch electrode 108 is arranged to face the surface of the counter substrate provided with the ground electrode 110, and the liquid crystal layer 114 is provided between the dielectric substrate 104 and the counter substrate. A thickness t of the liquid crystal layer 114 corresponds to a length from the surface of the patch electrode 108 on the liquid crystal layer 114 side to the surface of the ground electrode 110 on the liquid crystal layer 114 side.

Each layer formed on the dielectric substrate 104 is formed using the materials described below. For example, the undercoat layer 136 is formed of a silicon oxide film. For example, the first gate insulating layer 140 and the second gate insulating layer 146 are formed of a silicon oxide film or a stacked structure of a silicon oxide film and a silicon nitride film. The semiconductor layer is formed of a silicon semiconductor, such as amorphous silicon or polycrystalline silicon, and an oxide semiconductor containing a metal oxide, such as indium oxide, zinc oxide, and gallium oxide. For example, the first gate electrode 138 and the second gate electrode 148 may be composed of molybdenum (Mo), tungsten (W), or an alloy thereof. The first wiring 118, the second wiring 132, the first connecting wiring 144, and the second connecting wiring 152 are formed using a metal material such as titanium (Ti), aluminum (Al), or molybdenum (Mo). For example, the gate electrodes and wirings described above may be composed of a stacked structure of titanium (Ti)/aluminum (Al)/titanium (Ti), or a stacked structure of molybdenum (Mo)/aluminum (Al)/molybdenum (Mo). The planarization layer 156 is formed of a resin material such as acrylic or polyimide. For example, the passivation layer 158 is formed of a silicon nitride film or the like. The patch electrode 108 and the ground electrode 110 are formed of a metal film such as aluminum (Al), copper (Cu), or a transparent conductive film such as indium tin oxide (ITO).

As shown in FIG. 10, the second wiring 132 is connected to a gate of the transistor used as the switching element 134, the first wiring 118 is connected to one of the source and the drain of the transistor, and the patch electrode 108 is connected to the other of the source and the drain, whereby a predetermined patch electrode can be selected from the plurality of patch electrodes 108 arranged in a matrix, and the control voltage can be supplied. Furthermore, by providing the switching element 134 in the individual patch electrodes 108 in the absorbing surface 120, a control voltage can be supplied to each of the patch electrodes 108 arranged in a horizontal row along the first direction (X-axis direction) or each of the patch electrodes 108 arranged in a vertical row along the second direction (Y-axis direction).

### 2. Second Embodiment

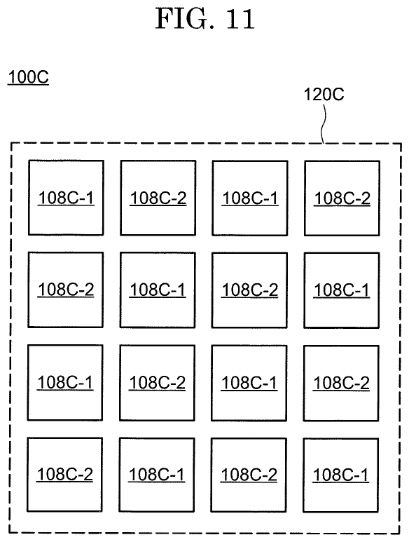

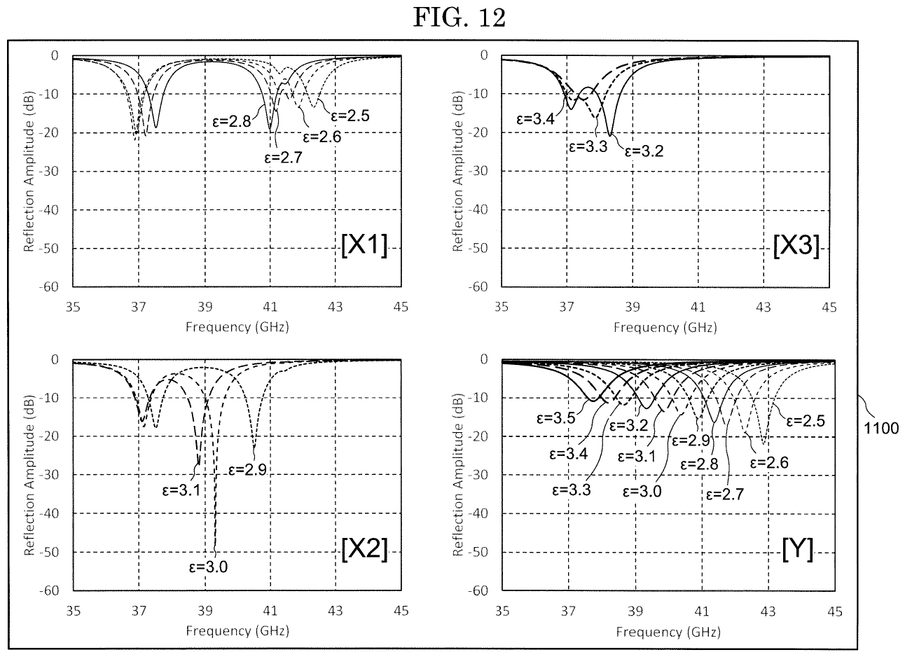

A radio wave absorption system 10C according to an embodiment of the present invention will be described with reference to FIG. 11 and FIG. 12. A configuration of the radio wave absorption system 10C according to the second embodiment is similar to that of the radio wave absorption system 10 according to the first embodiment. In the following description, descriptions of a configuration similar to that of the radio wave absorption system 10 will be omitted, and a configuration different from that of the radio wave absorption system 10 will be described. When a configuration similar to that of the first embodiment is described, FIG. 1 to FIG. 10 are used, and the description will be given with the letter “C” added to the reference signs shown in FIG. 1 to FIG. 10.

### [2-1. Radio Wave Absorption Device 100C]

A radio wave absorption device 100C in the radio wave absorption system 10C according to the present embodiment is controlled by the individual control method shown in FIG. 9. In the radio wave absorption device 100 according to the first embodiment, a control voltage is supplied collectively to all patch electrodes 108 provided on the absorbing surface 120. On the other hand, in the radio wave absorption device 100C according to the present embodiment, the patch electrodes 108C provided on an absorbing surface 120C are divided into a plurality of groups, and a control voltage is supplied to the patch electrodes 108C in groups. Specifically, the patch electrodes 108C are divided into a group formed of a first patch electrode 108C-1 and a group formed of a second patch electrode 108C-2.

Since the radio wave absorption device 100C is controlled by the individual control method, the first patch electrode 108C-1 and the second patch electrode 108C-2 can be controlled individually. Similar to the radio wave absorption device 100 according to the first embodiment, the radio wave absorption device 100C includes a ground electrode 110C (counter electrode) and a liquid crystal layer 114C. The ground electrode 110C (counter electrode) faces each of the first patch electrode 108C-1 and the second patch electrode 108C-2. The liquid crystal layer 114C is provided between the first patch electrode 108C-1 and the ground electrode 110 (counter electrode), and between the second patch electrode 108C-2 and the ground electrode 110 (counter electrode).

As shown in FIG. 11, the first patch electrode 108C-1 and the second patch electrode 108C-2 are arranged in a checkerboard pattern or a staggered pattern. That is, the first patch electrode 108C-1 is adjacent to the second patch electrode 108C-2 in each of the up, down, left, and right directions. Similarly, the second patch electrode 108C-2 is adjacent to the first patch electrode 108C-1 in each of the up, down, left, and right directions. The arrangement shown in FIG. 11 is an example of the present embodiment, and the present embodiment is not limited to this arrangement.

Different control voltages are supplied to the first patch electrode 108C-1 and the second patch electrode 108C-2, respectively. That is, the relative permittivity ε (first relative permittivity) of the liquid crystal layer 114C sandwiched between the first patch electrode 108C-1 and the ground electrode 110C is different from the relative permittivity ε (second relative permittivity) of the liquid crystal layer 114C sandwiched between the second patch electrode 108C-2 and the ground electrode 110C. For example, a control voltage is supplied to the first patch electrode 108C-1, and the same voltage as that of the ground electrode 110C is supplied to the second patch electrode 108C-2. That is, a potential difference based on the control voltage occurs between the first patch electrode 108C-1 and the ground electrode 110C. On the other hand, the potential difference between the second patch electrode 108C-2 and the ground electrode 110C is zero. As a result, the relative permittivity ε of the liquid crystal layer 114C belonging to the first patch electrode 108C-1 is 3.5. On the other hand, the relative permittivity ε of the liquid crystal layer 114C belonging to the second patch electrode 108C-2 is 2.5.

In the present embodiment, a configuration was exemplified in which a control voltage is supplied to the first patch electrode 108C-1 so that the relative permittivity ε of the liquid crystal layer 114C becomes 3.5, and a control voltage is supplied to the second patch electrode 108C-2 so that the relative permittivity ε of the liquid crystal layer 114C becomes 2.5. However, a control voltage other than the above may be supplied to the first patch electrode 108C-1 and the second patch electrode 108C-2. For example, the relative permittivity ε of the liquid crystal layer 114C belonging to the first patch electrode 108C-1 may be fixed at 3.5, and the relative permittivity ε of the liquid crystal layer 114C belonging to the second patch electrode 108C-2 may be adjusted within a range of 2.5 to 3.5.

### [2-2. Simulation Results of Radio Wave Absorption Device 100C]

FIG. 12 shows simulation results showing a relationship between a driving method for a radio wave absorption device and radio wave absorption in a radio wave absorption device according to an embodiment of the present invention. The simulation results 1100 shown in FIG. 12 are the results of simulating the reflection characteristics of an absorbing surface unit cell 102C arranged in a 2×2 matrix. This simulation was performed using CST Studio Suite (manufactured by Dassault Systemes K.K.). The parameters of the radio wave absorption device 100C used in the simulation are as follows.
Arrangement pitch of the patch electrode 108C: 3 mm
Size of the patch electrode 108C: 2 mm×2 mm
Thickness of the liquid crystal layer: 30 μm
Relative permittivity ε of the liquid crystal layer 114C belonging to the first patch electrode 108C-1: 3.5
Relative permittivity ε of the liquid crystal layer 114C belonging to second patch electrode 108C-2: 2.5 to 3.4
Thickness of a substrate 101C: 1.0 mm

FIG. 12 shows four simulation results. The simulation results indicated by [X1] to [X3] are simulation results calculated using the parameters described above.

The simulation result indicated by [X1] is obtained when the relative permittivity ε of the liquid crystal layer 114C belonging to the second patch electrode 108C-2 is 2.5 to 2.8. The simulation result indicated by [X2] is obtained when the relative permittivity ε of the liquid crystal layer 114C belonging to the second patch electrode 108C-2 is 2.9 to 3.1. The simulation result indicated by [X 3] is obtained when the relative permittivity ε of the liquid crystal layer 114C belonging to the second patch electrode 108C-2 is 3.2 to 3.4.

The simulation result indicated by [Y] is the simulation result for the radio wave absorption device 100 according to the first embodiment, not for the radio wave absorption device 100C according to the present embodiment. That is, the simulation result indicated by [Y] is the simulation result when the relative permittivities ε of the liquid crystal layer 114 belonging to all patch electrodes 108 are the same.

As shown in the graph [X2] of FIG. 12, when the relative permittivity ε of the liquid crystal

layer 114C belonging to the first patch electrode 108C-1 is 3.5 and the relative permittivity ε of the liquid crystal layer 114C belonging to the second patch electrode 108C-2 is 3.0, the frequency at which the reflection amplitude has a minimum value is 39.3 GHz. The minimum value in this case is approximately −48 dB.

On the other hand, in the collective control method shown in the first embodiment, when the frequency at which the reflection amplitude has a minimum value is adjusted to approximately 39.3 GHz, it is necessary to control the relative permittivity ε of the liquid crystal layer 114 to 3.2. However, as shown in the graph [Y] of FIG. 12, the minimum value of the reflection amplitude when the relative permittivity ε of the liquid crystal layer 114 is 3.2 in the collective control method is approximately −13 dB. That is, the minimum value of the reflection amplitude can be made smaller using the individual control method to control the minimum value of the reflection amplitude to a desired frequency rather than using the collective control method to control the minimum value of the reflection amplitude to a desired frequency.

Similar to the first embodiment, when the first patch electrode 108C-1 and the ground electrode 110C are made of different materials, the minimum value of the reflection amplitude is smaller than the minimum value of the reflection amplitude when the first patch electrode 108C-1 and the ground electrode 110C are made of the same material. Similarly, when the second patch electrode 108C-2 and the ground electrode 110C are made of different materials, the minimum value of the reflection amplitude is smaller than the minimum value of the reflection amplitude when the second patch electrode 108C-2 and the ground electrode 110C are made of the same material. That is, by using different materials for the opposing electrodes, the amount of radio waves absorbed by the radio wave absorption device 100C can be increased.

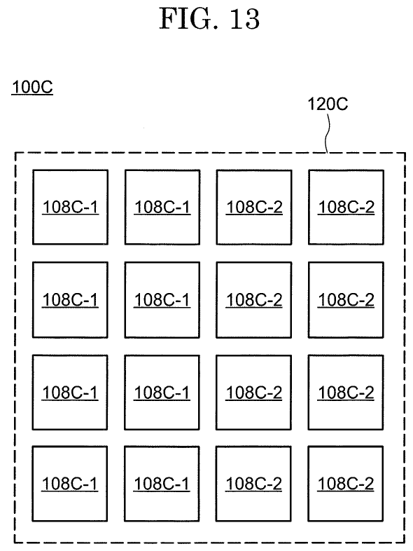

Although a configuration in which the first patch electrode 108C-1 and the second patch electrode 108C-2 are arranged in a checkerboard pattern or a staggered pattern was exemplified in the present embodiment, the present embodiment is not limited to this configuration. For example, the first patch electrode 108C-1 and the second patch electrode 108C-2 may be arranged as shown in FIG. 13. That is, the first patch electrodes 108C-1 may be adjacent to each other, and the second patch electrodes 108C-2 may be adjacent to each other.

### 3. Third Embodiment

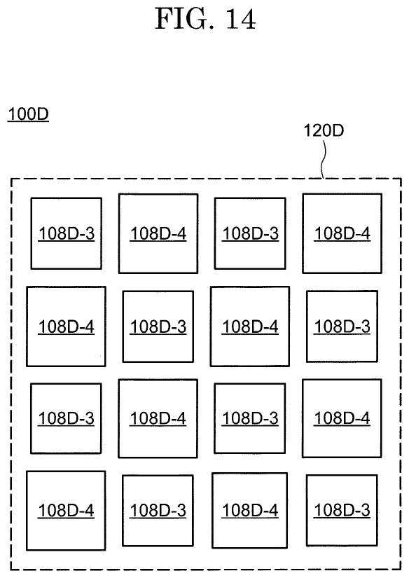

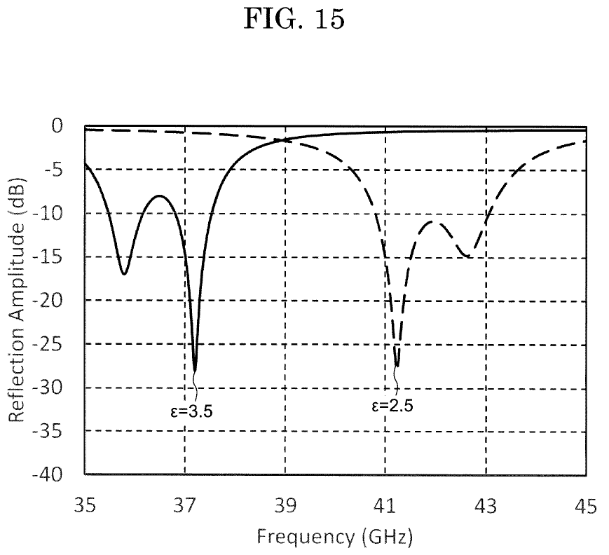

A radio wave absorption system 10D according to an embodiment of the present invention will be described with reference to FIG. 14 and FIG. 15. A configuration of the radio wave absorption system 10D according to the third embodiment is similar to that of the radio wave absorption system 10 according to the first embodiment. In the following description, descriptions of a configuration similar to that of the radio wave absorption system 10 will be omitted, and a configuration different from that of the radio wave absorption system 10 will be described. When a configuration similar to that of the first embodiment is described, FIG. 1 to FIG. 10 are used, and the description will be given with the letter “D” added to the reference signs shown in FIG. 1 to FIG. 10.

### [3-1. Radio Wave Absorption Device 100D]

Either the collective control method shown in FIG. 8 or the individual control method shown in FIG. 9 may be used in a radio wave absorption device 100D in the radio wave absorption system 10D according to the present embodiment. In the radio wave absorption device 100 according to the first embodiment, the sizes (for example, side lengths) of all patch electrodes 108 provided on the absorbing surface 120 are the same. On the other hand, in the radio wave absorption device 100D according to the present embodiment, patch electrodes 108D provided on an absorbing surface 120D are divided into a plurality of groups, and the sizes of the patch electrodes 108D are different in groups.

Specifically, as shown in FIG. 14, the patch electrodes 108D are divided into a group formed of first patch electrodes 108D-3 and a group formed of second patch electrodes 108D-4. The size of the first patch electrode 108D-3 is different from the size of the second patch electrode 108D-4. In the example of FIG. 14, the size of the first patch electrode 108D-3 is smaller than the size of the second patch electrode 108D-4. The size of the second patch electrode 108D-4 may be within ±10% of the size of the first patch electrode 108D-3.

The first patch electrode 108D-3 and the second patch electrode 108D-4 are supplied with the same control voltage. That is, the relative permittivity ε (first relative permittivity) of a liquid crystal layer 114D sandwiched between the first patch electrode 108D-3 and a ground electrode 110D is the same as the relative permittivity ε (second relative permittivity) of the liquid crystal layer 114D sandwiched between a second patch electrode 108D-2 and the ground electrode 110D.

As shown in FIG. 14, the first patch electrode 108D-3 and the second patch electrode 108D-4 are arranged in a checkerboard pattern or a staggered pattern. That is, the first patch electrode 108D-3 is adjacent to the second patch electrode 108D-4 in each of the up, down, left, and right directions. Similarly, the second patch electrode 108D-4 is adjacent to the first patch electrode 108D-3 in each of the up, down, left, and right directions. The arrangement shown in FIG. 14 is an example of the present embodiment, and the present embodiment is not limited to this arrangement.

### [3-2. Simulation Results of Radio Wave Absorption Device 100D]

FIG. 15 shows simulation results showing a relationship between a driving method for the radio wave absorption device and radio wave absorption, in the radio wave absorption device according to an embodiment of the present invention. The simulation results shown in FIG. 15 are the results of simulating the reflection characteristics of an absorbing surface unit cell 102D arranged in a 2×2 matrix. This simulation was performed using CST Studio Suite (manufactured by Dassault Systemes K.K.). The parameters of the radio wave absorption device 100D used in the simulation are as follows.
Arrangement pitch of the patch electrode 108D: 3 mm
Size of the first patch electrode 108D-3: 2 mm×2 mm
Size of the second patch electrode 108D-4: 2.1 mm×2.1 mm
Thickness of the liquid crystal layer: 30 μm
Relative permittivity ε of the liquid crystal layer 114D: 2.5, 3.5
Thickness of a substrate 101D: 0.8 mm

FIG. 15 shows two simulation results. These simulation results are obtained for the liquid crystal layer 114D with different relative permittivities (ε=2.5, 3.5), respectively. In FIG. 15, the simulation result when the relative permittivity ε is 2.5 is shown by a dotted line, and the simulation result when the relative permittivity ε is 3.5 is shown by a solid line. In the radio wave absorption device 100D, the simulation result when the relative permittivity ε is 2.5 corresponds to the simulation result when no control voltage is supplied to the patch electrode 108D and the ground electrode 110D (a state in which the potential difference between the patch electrode 108D and the ground electrode 110D is zero). On the other hand, the simulation result when the relative permittivity ε is 3.5 corresponds to the simulation result when the control voltages are supplied to the patch electrode 108D and the ground electrode 110D. The relative permittivity ε can be adjusted in the range of 2.5 to 3.5 by the control voltages supplied to the patch electrode 108D and the ground electrode 110D.

As shown in FIG. 15, regardless of the value of the relative permittivity ε, the spectrum showing the reflection amplitude has two minimum values. As a result, compared with the simulation results shown in FIG. 5, the simulation results shown in FIG. 15 indicate that the frequency band of the radio waves that can be absorbed by the radio wave absorption device 100D is wider. That is, as described above, by varying the size of the patch electrodes 108D, the frequency band of the radio waves that can be absorbed by the radio wave absorption device 100D can be widened. The arrangement of the first patch electrode 108D-3 and the second patch electrode 108D-4 may be an arrangement in which the first patch electrodes 108D-3 are adjacent to each other, as shown in FIG. 13, or an arrangement in which the second patch electrodes 108D-4 are adjacent to each other.

### 4. Fourth Embodiment

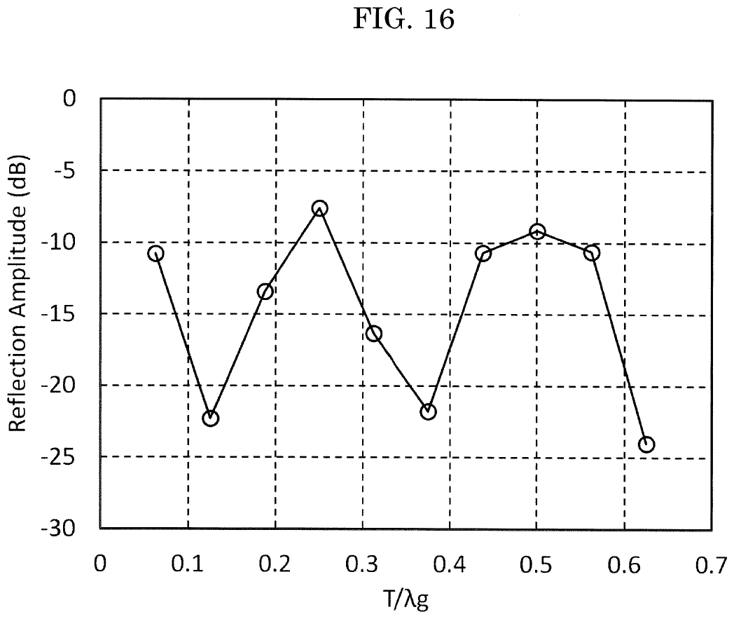

A radio wave absorption system 10E according to an embodiment of the present invention will be described with reference to FIG. 16. A configuration of the radio wave absorption system 10E according to the fourth embodiment is similar to that of the radio wave absorption system 10 according to the first embodiment. In the following description, descriptions of a configuration similar to that of the radio wave absorption system 10 will be omitted, and a configuration different from that of the radio wave absorption system 10 will be described. When a configuration similar to that of the first embodiment is described, FIG. 1 to FIG. 10 are used, and the description will be given with the letter “E” added to the reference signs shown in FIG. 1 to FIG. 10.

### [4-1. Simulation Results of Radio Wave Absorption Device 100E]

Either the collective control method shown in FIG. 8 or the individual control method shown in FIG. 9 may be used in a radio wave absorption device 100E in the radio wave absorption system 10E according to the present embodiment. In the radio wave absorption device 100E according to the present embodiment, a substrate 101E having a thickness suitable for absorbing radio waves is provided.

FIG. 16 shows simulation results showing a relationship between the thickness of the substrate and radio wave absorption, in a radio wave absorption device according to an embodiment of the present invention. The simulation results shown in FIG. 16 are the results of simulating the reflection characteristics of an absorbing surface unit cell 102E. This simulation was performed using CST Studio Suite (manufactured by Dassault Systemes K.K.). The parameters of the radio wave absorption device 100E used in the simulation are as follows.
Arrangement pitch of a patch electrode 108E: 3 mm
Size of the patch electrode 108E: 2 mm×2 mm
Thickness of the liquid crystal layer: 30 μm
Relative permittivity ε of a liquid crystal layer 114E: 2.5, 3.5
Thickness of the substrate 101E: 0.2 mm to 2.0 mm

FIG. 16 is a graph plotting the minimum values of the reflection amplitude under each condition in the simulation results as shown in FIG. 5. In the graph shown in FIG. 16, the vertical axis represents the reflection amplitude, and the horizontal axis represents a value (T/λ_{g}) obtained by dividing the thickness (T) of the substrate 101E relative to the wavelength of the radio wave used as a simulation parameter by the wavelength (λ_{g}) of the radio wave propagating through the substrate 101E. The value of the reflection amplitude in FIG. 16 is the average value of the minimum value of the reflection amplitude when the relative permittivity ε of the liquid crystal layer 114E is 2.5 and the minimum value of the reflection amplitude when the relative permittivity ε is 3.5. As shown in FIG. 16, the minimum value of the reflection amplitude exhibits periodic behavior with respect to the thickness of the substrate 101E. This behavior is considered to be due to the interference effect of radio waves reflected by the radio wave absorption device 100E. Specifically, the reflection amplitude tends to be small under the conditions where the thickness T of the substrate 101E is different from ¼ of the wavelength of the radio wave incident on the radio wave absorption device 100E. More specifically, the reflection amplitude tends to be small under the conditions where the thickness T of the substrate 101E is λ_{g}/8+(n−1)λ_{g}/4. Therefore, for example, by setting the thickness of the substrate 101E to λ/8, the apparent amount of radio waves absorbed by the radio wave absorption device 100E can be increased due to the interference effect of the reflected waves.

### 5. Fifth Embodiment

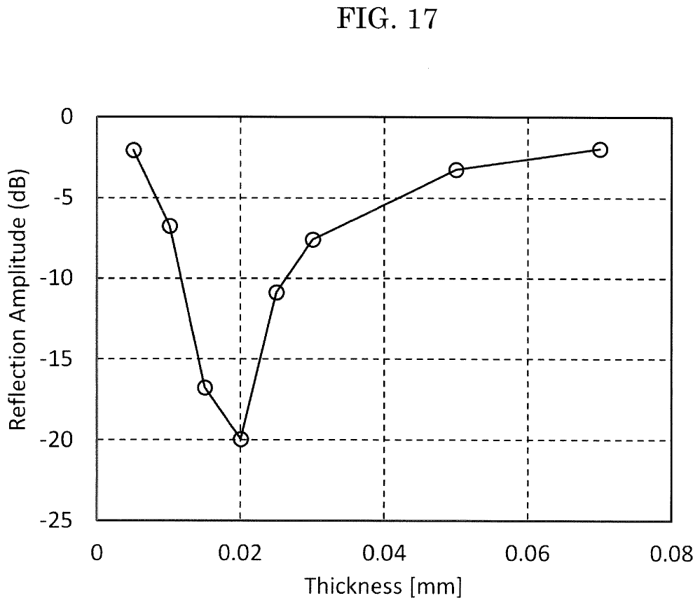

A radio wave absorption system 10F according to an embodiment of the present invention will be described with reference to FIG. 17. A configuration of the radio wave absorption system 10F according to the fifth embodiment is similar to that of the radio wave absorption system 10 according to the first embodiment. In the following description, descriptions of a configuration similar to that of the radio wave absorption system 10 will be omitted, and a configuration different from that of the radio wave absorption system 10 will be described. When a configuration similar to that of the first embodiment is described, FIG. 1 to FIG. 10 are used, and the description will be given with the letter “F” added to the reference signs shown in FIG. 1 to FIG. 10.

### [5-1. Simulation Results of Radio Wave Absorption Device 100F]

Either the collective control method shown in FIG. 8 or the individual control method shown in FIG. 9 may be used in a radio wave absorption device 100F in the radio wave absorption system 10F according to the present embodiment. In the radio wave absorption device 100F according to the present embodiment, a liquid crystal layer 114F having a thickness suitable for absorbing radio waves is provided.

FIG. 17 shows simulation results showing a relationship between a thickness of a substrate and radio wave absorption, in a radio wave absorption device according to an embodiment of the present invention. The simulation results shown in FIG. 17 are the results of simulating the reflection characteristics of an absorbing surface unit cell 102F. This simulation was performed using CST Studio Suite (manufactured by Dassault Systemes K.K.). The parameters of the radio wave absorption device 100F used in the simulation are as follows.
Arrangement pitch of a patch electrode 108F: 3 mm
Size of the patch electrode 108F: 2 mm×2 mm
Thickness of the liquid crystal layer: 5 μm to 70 μm
Relative permittivity ε of the liquid crystal layer 114F: 2.5, 3.5
Thickness of a substrate 101F: 0.8 mm

Similar to FIG. 16, FIG. 17 is a graph plotting the minimum values of the reflection amplitude under each condition. In the graph shown in FIG. 17, the horizontal axis represents the thickness of the liquid crystal layer 114F. The value of the reflection amplitude in FIG. 17 is the average value of the minimum value of the reflection amplitude when the relative permittivity ε of the liquid crystal layer 114F is 2.5 and the minimum value of the reflection amplitude when the relative permittivity ε is 3.5. As shown in FIG. 17, by adjusting the thickness of the liquid crystal layer 114F to a range of 10 μm or more and 40 μm or less, the amount of radio waves absorbed by the radio wave absorption device 100F can be increased.

### 6. Sixth Embodiment

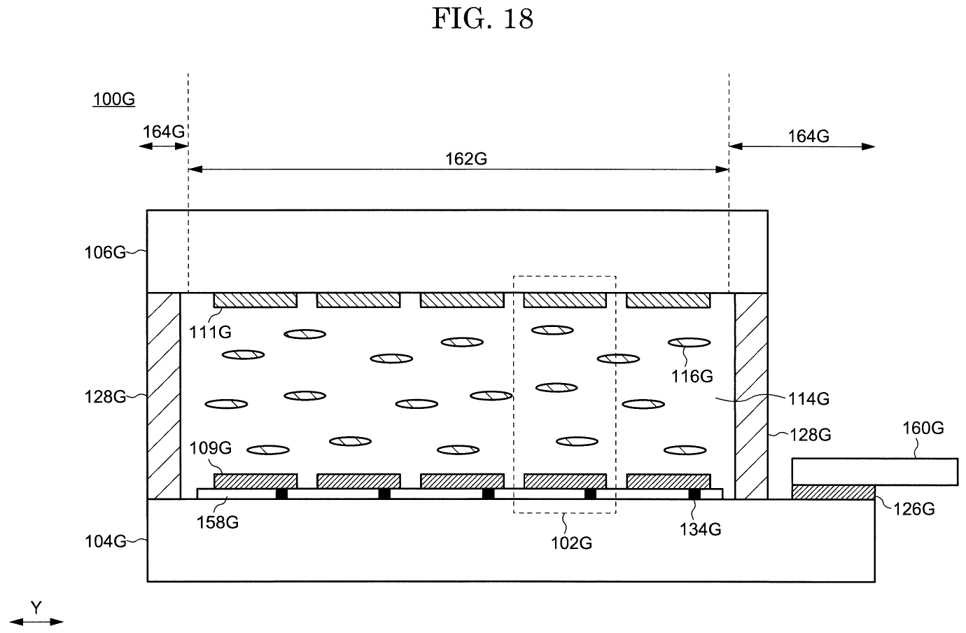

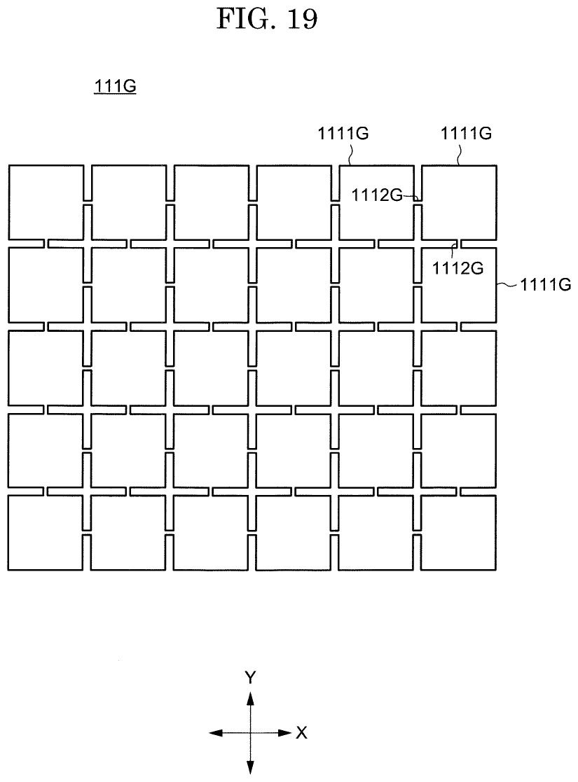

A radio wave absorption device 100G according to an embodiment of the present invention will be described with reference to FIG. 18 and FIG. 19. A configuration of the radio wave absorption device 100G according to the sixth embodiment is similar to the configuration of the radio wave absorption device 100 according to the first embodiment. In the following description, descriptions of a configuration similar to that of the radio wave absorption device 100 will be omitted, and a configuration different from the radio wave absorption device 100 will be described. In the following description, when a configuration similar to that of the first embodiment is described, FIG. 1 to FIG. 10 are used, and the description will be given with the letter “G” added to the reference signs shown in FIG. 1 to FIG. 10.

### [6-1. Radio Wave Absorption Device 100G]

FIG. 18 is a cross-sectional view showing an overview of a radio wave absorption device according to an embodiment of the present invention. As shown in FIG. 18, the radio wave absorption device 100G includes a plurality of absorbing elements (absorbing surface unit cells) 102G. The plurality of absorbing surface unit cells 102G is arranged in at least one direction. In FIG. 18, the plurality of absorbing surface unit cells 102G is arranged in the Y-axis direction. The radio wave absorption device 100G includes a dielectric substrate 104G, a counter substrate 106G, a drive electrode 109G (counter electrode), a patch electrode 111G, a liquid crystal layer 114G, a sealing material 128G, a switching element 134G, a terminal portion 126G, and an FPG 160G. The liquid crystal layer 114G contains a liquid crystal molecule 116G. In this configuration, the electrode 111G provided on the counter substrate 106G side functions as a patch electrode that absorbs radio waves. The liquid crystal is aligned according to the potential difference between the potential applied to the drive electrode 109G and the potential applied to the patch electrode 111G, thereby changing the dielectric constant. A passivation layer 158G is provided between the drive electrode 109G and the dielectric substrate 104G.

The absorbing surface unit cell 102G includes at least the drive electrode 109G, the patch electrode 111G, the liquid crystal layer 114G, and the switching element 134G. Although the patch electrode 111G appears to be provided individually for each absorbing surface unit cell 102G in FIG. 18, it is actually provided in common for the plurality of absorbing surface unit cells 102G as shown in FIG. 19. The drive electrode 109G is provided on the dielectric substrate 104G side. The drive electrode 109G faces the patch electrode 111G and is provided individually for each absorbing surface unit cell 102G. The patch electrode 111G is provided on the counter substrate 106G side.

The switching element 134G is connected to the drive electrode 109G. In FIG. 18, the drive electrode 109G is arranged on the switching element 134G so as to overlap the switching element 134G. This makes the switching element 134G less susceptible to the effects of radio waves. The switching element 134G is driven by a drive circuit 600G (see FIG. 1). The alignment of the liquid crystal molecule 116G is controlled according to the driving state of the switching element 134G. As described above, by controlling the alignment of the liquid crystal molecule 116G, the frequency band of the radio waves absorbed by the radio wave absorption device 100G can be adjusted.

As described above, in the case of the radio wave absorption device 100G according to the present embodiment, since the radio waves incident on the radio wave absorption device 100G are shielded or absorbed by the patch electrode 111G, it is possible to suppress adverse effects such as heat generation in the switching element 134G due to the irradiation of the radio waves.

### [6-2. Drive Electrode 109G]

FIG. 19 is a plan view showing an overview of a patch electrode of a radio wave absorption device according to an embodiment of the present invention. As shown in FIG. 19, the patch electrode 111G includes a resonant portion 1111G and a connecting portion 1112G.

The resonant portion 1111G is a portion that resonates with the wavelength of the radio wave incident on the radio wave absorption device 100G, and is arranged in a matrix in the X-axis direction and the Y-axis direction. The size of the resonant portion 1111G in the X-axis direction and the Y-axis direction is calculated using the dielectric constant of the liquid crystal layer 114G and the like, in addition to the wavelength of the radio wave.

The connecting portion 1112G connects the resonant portions 1111G adjacent in the X-axis direction or the Y-axis direction. The resonant portions 1111G arranged in a matrix are electrically connected by the connecting portion 1112G. Therefore, the resonant portions 1111G arranged in a matrix are at the same potential. The connecting portion 1112G has a longitudinal direction in the X-axis direction or the Y-axis direction. The connecting portion 1112G connecting the resonant portions 1111G adjacent in the X-axis direction has a longitudinal direction in the X-axis direction. The connecting portion 1112G connecting the resonant portions 1111G adjacent in the Y-axis direction has a longitudinal direction in the Y-axis direction.

A width (width in the Y-axis direction) of the connecting portion 1112G having a longitudinal direction in the X-axis direction is 1/100 or less of the size of the resonant portion 1111G in the Y-axis direction. A width (width in the X-axis direction) of the connecting portion 1112G having a longitudinal direction in the Y-axis direction is 1/100 or less of the size of the resonant portion 1111G in the X-axis direction. With this configuration, the connecting portion 1112G can reduce the influence of resonance of the resonant portion 1111G.

Various configurations of the radio wave absorption device and the absorbing surface unit exemplified as an embodiment of the present invention can be appropriately combined as long as no contradiction is caused. Further, the addition, deletion, or design change of components, or the addition, deletion, or condition change of processes as appropriate by those skilled in the art based on the radio wave absorption device and the absorbing surface unit are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention. What is claiemd is:

1. A radio wave absorption device comprising:
a patch electrode;
a counter electrode facing the patch electrode and formed of a material different from a material of the patch electrode; and
a liquid crystal layer between the patch electrode and the counter electrode.

2. The radio wave absorption device according to claim 1, wherein an electrical conductivity of a material forming the patch electrode is different from an electrical conductivity of a material forming the counter electrode.

3. The radio wave absorption device according to claim 1, wherein a ratio of an electrical conductivity of a material forming the patch electrode to an electrical conductivity of a material forming the counter electrode is ten times or more.

4. The radio wave absorption device according to claim 1, wherein
when a material of the patch electrode is a metal, a material of the counter electrode is a transparent conductive material, and
when the material of the patch electrode is a transparent conductive material, the material of the counter electrode is a metal.

5. The radio wave absorption device according to claim 1, further comprising a substrate provided on a side on which radio waves are incident on the radio wave absorption device with respect to the liquid crystal layer,
wherein a thickness of the substrate is different from λ/4 with respect to a wavelength λ of the radio waves incident on the radio wave absorption device.

6. The radio wave absorption device according to claim 1, wherein a thickness of the liquid crystal layer is 10 μm or more and 40 μm or less.

7. A radio wave absorption device comprising:
a first patch electrode;
a second patch electrode independently controllable from the first patch electrode;
a counter electrode facing the first patch electrode and the second patch electrode; and
a liquid crystal layer between the first patch electrode and the counter electrode and between the second patch electrode and the counter electrode,
wherein a first relative permittivity of the liquid crystal layer sandwiched between the first patch electrode and the counter electrode is different from a second relative permittivity of the liquid crystal layer sandwiched between the second patch electrode and the counter electrode.

8. The radio wave absorption device according to claim 7, wherein
a material forming the first patch electrode is different from a material forming the counter electrode, and
a material forming the second patch electrode is different from the material forming the counter electrode.

9. The radio wave absorption device according to claim 7, wherein a ratio of an electrical conductivity of a material forming the patch electrode to an electrical conductivity of a material forming the counter electrode is ten times or more.

10. The radio wave absorption device according to claim 7, wherein
when a material of the patch electrode is a metal, a material of the counter electrode is a transparent conductive material, and
when the material of the patch electrode is a transparent conductive material, the material of the counter electrode is a metal.

11. The radio wave absorption device according to claim 7, further comprising a substrate provided on a side on which radio waves are incident on the radio wave absorption device with respect to the liquid crystal layer,
wherein a thickness of the substrate is different from λ/4 with respect to a wavelength λ of the radio waves incident on the radio wave absorption device.

12. The radio wave absorption device according to claim 7, wherein a thickness of the liquid crystal layer is 10 μm or more and 40 μm or less.

13. The radio wave absorption device according to claim 7, wherein a size of the first patch electrode is different from a size of the second patch electrode.

14. A radio wave absorption system comprising:
the radio wave absorption device according to claim 1; and
a control device configured to control voltages supplied to the patch electrode and the counter electrode,
wherein the control device is configured to control the voltages supplied to the patch electrode and the counter electrode to vary an absorption amount of the radio wave absorption device with respect to radio waves having an arbitrary frequency.

15. The radio wave absorption device according to claim 14,
wherein the control device is configured to:
receive a set value relating to a frequency of radio waves to be absorbed by the radio wave absorption device; and
control the voltages supplied to the patch electrode and the counter electrode based on the set value.

16. A radio wave absorption system comprising:
the radio wave absorption device according to claim 7; and
a control device configured to control voltages supplied to the first patch electrode, the second patch electrode and the counter electrode,
wherein the control device is configured to control the voltages supplied to the first patch electrode, the second patch electrode and the counter electrode to vary an absorption amount of the radio wave absorption device with respect to radio waves having an arbitrary frequency.

17. The radio wave absorption device according to claim 16,
wherein the control device is configured to:
receive a set value relating to a frequency of radio waves to be absorbed by the radio wave absorption device; and
control the voltages supplied to the patch electrode and the counter electrode based on the set value.
